(19) United States
(12) Patent Application Publication
(10) Pub. No.: US 2018/0098443 A1
(43) Pub. Date: Apr. 5, 2018

(54) USE OF A MULTI-START SCREW THREAD IN AN EX-D HOUSING

(71) Applicant: Endress+Hauser GmbH+Co. KG, Maulburg (DE)

(72) Inventors: Andreas Krumbholz, Maulburg (DE); Robert Schmidt, Schopfheim (DE)

(21) Appl. No.: 15/567,821

(22) PCT Filed: Mar. 24, 2016
(86) PCT No.: PCT/EP2016/056592

§ 371 Date: Oct. 19, 2017

(30) Foreign Application Priority Data
Apr. 24, 2015 (DE) 10 2015 106 350.6

(51) Int. Cl. H05K 5/02

(52) U.S. Cl. CPC H05K 5/0239

(57) ABSTRACT

The invention relates to a field device of automation technology, including a housing with an opening for accommodating field device components, wherein the housing has at an edge of the opening a first screw thread, a lid for closing the opening of the housing, wherein the lid has at an edge of the lid a second screw thread, wherein the first and second screw threads are embodied to be complementary to one another, so that the housing after closing by means of the lid fulfills all Ex-d requirements, wherein the first and second screw threads are embodied as multi-start screw threads.

The invention relates to a field device of automation technology, comprising a housing and a lid for closing the housing, wherein the housing after closing by means of the lid fulfills all Ex-d requirements.

In automation technology, especially in process and manufacturing automation technology, field devices are often applied, which serve for registering and/or influencing process variables. Serving for registering process variables are sensors, such as, for example, fill level measuring devices, flow measuring devices, pressure- and temperature measuring devices, pH-redox potential measuring devices, conductivity measuring devices, etc., which register the corresponding process variables, fill level, flow, pressure, temperature, pH-value, and conductivity. Serving for influencing process variables are actuators, such as, for example, valves or pumps, via which the flow of a liquid in a pipeline section or the fill level in a container can be changed. Referred to as field devices are, in principle, all devices, which are applied near to the process and which deliver, or process, process relevant information. In connection with the invention, referred to as field devices are also remote I/Os, radio adapters, and, in general, devices, which are arranged at the field level and communicate via a data bus with one another. Often, also network components are considered to be field devices. A large number of such field devices or network components are produced and sold by the firm, Endress+Hauser.

Field devices usually have a housing for accommodating an electronics unit and a sensor unit. The housing is embodied pot shaped and is in many cases manufactured of a non-conductive material. Used as materials are plastics and composite materials. The housing can, however, also be made of a metal or a metal alloy. Typically, a housing of a fill-level measuring device is composed of 60% aluminum, 25% plastic and 15% stainless steel and a housing of a pressure measuring device is composed only of aluminum and stainless steel and no plastic.

Implemented in the state of the art by means of a single-start metric thread, e.g. m80×1.5, is a releasable connection between an Ex-d housing (Ex-d=explosion protection−pressure-resistant encapsulation) and an Ex-d lid. The embodiment according to the Ex-d standard requires at least seven engaged screw threads, in order to assure flame penetration resistance over the gap length. With extra for chamfer and thread runout, the thread length is about 13.5 mm (7×1.5 mm+3 mm extra), which, in practice, means about eight revolutions of the lid. This is not optimal for the internal assembly of the field device components and the maintenance of the field device, since it is, on the one hand, time consuming and, on the other hand, ergonomically to unfavorable in requiring too much twisting motion.

An object of the invention is to provide a field device of automation technology, which fulfills the Ex-d requirements and, in spite of this, can be rapidly screwed open and closed.

The object is achieved according to the invention by the subject matter of the invention. Subject matter of the invention is a field device of automation technology, comprising a housing with an opening for accommodating field device components, wherein the housing has at an edge of the opening a first screw thread, a lid for closing the opening of the housing, wherein the lid has at an edge of the lid a second screw thread, wherein the first and second screw threads are embodied to be complementary to one another, so that the housing after closing by means of the lid fulfills all Ex-d requirements, characterized in that the first and second screw threads are embodied as multi-start screw threads.

By running individual threads in parallel with increased slopes, the number of revolutions is reduced and, thus, a faster screwing together with less revolutions is possible. Furthermore, the increased slope of the screw threads at equal tightening torque means less prestress in the screw thread, which, in turn, means that the lid can be opened more easily. At the same time, the path for the flame penetration resistance, and for ignition sparks, remains the same.

In an advantageous embodiment, the first and second screw threads are embodied as a four-start screw thread.

In an advantageous form of embodiment, the first and second screw threads have axially at least five, preferably eight starts.

An object of the invention is likewise achieved through the use of a multi-start thread in a lid-closing mechanism of an Ex-d requirements fulfilling housing of a field device of to automation technology.

The invention will now be explained in greater detail based on the appended drawing, the figures of which show as follows:

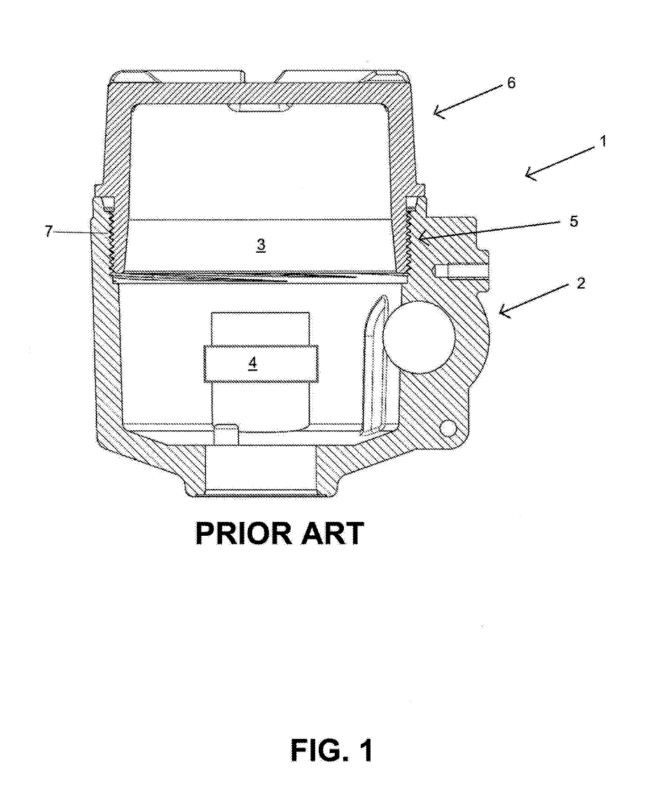

FIG. 1 a longitudinal section of a housing of a field device of automation technology according to the state of the art, and

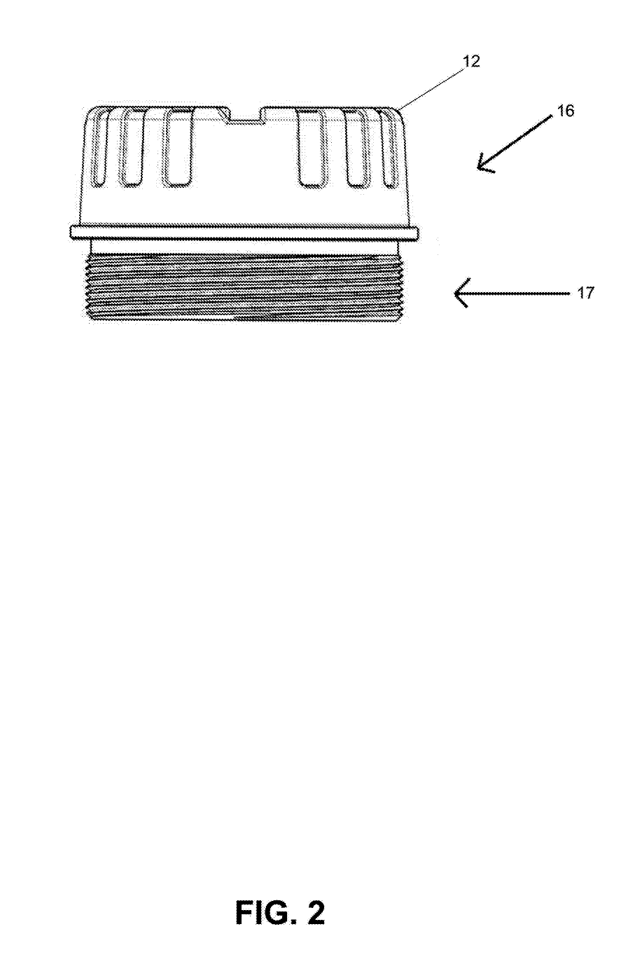

FIG. 2 a front view of a lid of the invention with four screw threads extending in parallel to form a four-start screw thread for a housing with a four-start screw thread.

FIG. 1 shows a longitudinal section of a housing 1 of a field device 1 of automation technology according to the state of the art. Housing 1 includes a housing 2 and a lid 6. The housing 2 and the lid 6 are pot shaped. The housing 2 is fashioned to accommodate field device components 4 and includes, for this purpose, an opening 3. The housing 2 includes in an outer edge region at the opening 3 a first screw thread 5. The lid 6 includes in an outer edge region a second screw thread 7.

The first and second screw threads 5, 7 are complementary to one another. If the housing 2 is closed by means of the lid 6, housing 1 fulfills all Ex-d requirements.

FIG. 2 shows a front view of a lid 6 of the invention for a housing 2 with a four-start screw thread. The second screw thread 7 of the lid 6 is embodied as a four-start screw thread. Lid 6 has in another embodiment a second screw thread 7 with eight starts.

### LIST OF REFERENCE CHARACTERS

1 housing of a field device of automation technology

2 housing

3 opening

4 field device components

5 first screw thread

6 lid

7 second screw thread

1-4. (canceled)

5. A field device of automation technology, comprising
a housing with an opening for accommodating field device components, wherein the housing has at an edge of the opening a first screw thread; and
a lid for enclosing the opening of the housing, wherein the lid has at an edge of the lid a second screw thread,
wherein the first screw thread and the second screw thread are embodied to be complementary to one another, such that the housing after enclosing with the lid fulfills all Ex-d requirements, and
wherein the first screw thread and the second screw thread are embodied as multi-start screw threads.

6. The field device of claim 5, wherein the first screw thread and the second screw thread are embodied as four-start screw threads.

7. The field device of claim 5, wherein the first screw thread and the second screw thread have axially at least five starts.

8. The field device of claim 5, wherein the first screw thread and the second screw thread have axially eight starts.

9. A lid-closing mechanism of a field device of automation technology, comprising a housing embodied to fulfill all Ex-d requirements, the housing including lid-closing mechanism having a multi-start thread.
